(19) United States
(12) Patent Application Publication
(10) Pub. No.: US 2022/0402394 A1
(43) Pub. Date: Dec. 22, 2022

(54) CONTACTLESS POWER SUPPLY SYSTEM, POSITION ESTIMATION METHOD, MOBILE BODY, AND POWER SUPPLY DEVICE

(71) Applicant: TOYOTA JIDOSHA KABUSHIKI KAISHA, Aichi-ken (JP)

(72) Inventors: Shuntaro OKAZAKI, Sunto-gun (JP); Kazuhisa MATSUDA, Sunto-gun (JP); Daiki YOKOYAMA, Gotemba-shi (JP)

(21) Appl. No.: 17/734,120

(22) Filed: May 2, 2022

(30) Foreign Application Priority Data
Jun. 17, 2021 (JP) 2021-101215

(51) Int. Cl. B60L 53/39; B60L 53/126; H02J 50/90; H02J 50/10

(52) U.S. Cl. CPC B60L 53/39; B60L 53/126; H02J 50/90; H02J 50/10

(57) ABSTRACT

Provided is a contactless power supply system including a transmission-side resonance circuit configured to transmit electric power, a reception-side resonance circuit configured to receive the electric power from the transmission-side resonance circuit, an alternating current magnetic field generation circuit configured to generate an alternating current magnetic field for detecting a relative positional relationship between the transmission-side resonance circuit and the reception-side resonance circuit, and a magnetic field detector configured to detect the alternating current magnetic field. The contactless power supply system performs contactless electric power transmission of magnetic field resonance coupling between a ground-side device and a mobile body. A frequency of the position detecting alternating current magnetic field is different from a resonance frequency of each of the transmission-side resonance circuit and the reception-side resonance circuit.

### CROSS-REFERENCE TO RELATED APPLICATION

This application claims priority to Japanese Patent Application No. 2021-101215 filed on Jun. 17, 2021, incorporated herein by reference in its entirety.

### BACKGROUND

### 1. Technical Field

The present disclosure relates to a contactless power supply system, a position estimation method, a mobile body, and a power supply device.

### 2. Description of Related Art

Hitherto, there is known a technology for contactless transmission of electric power between aground-side device provided on the ground and a mobile body such as a vehicle using a transmission method such as magnetic field coupling (electromagnetic induction), electric field coupling, magnetic field resonance coupling (magnetic field resonance), or electric field resonance coupling (electric field resonance). Particularly in contactless electric power transmission of magnetic field resonance coupling using a transmission-side resonance circuit and a reception-side resonance circuit having the same resonance frequency, large electric power can be transmitted via an alternating current magnetic field generated in the transmission-side resonance circuit even if the mobile body and the ground-side device me located away from each other.

However, constant generation of the alternating current magnetic field for electric power transmission between the ground-side device and the mobile body leads to a waste of electric power. There is also concern about influence of the alternating current magnetic field on electronic devices or the like. Therefore, it is desirable to generate the alternating current magnetic field for electric power transmission at an appropriate timing when the mobile body passes over the ground-side device.

In this regard, Japanese Unexamined Patent Application Publication No. 2018-157686 (JP 2018-157686 A) describes that, when a power supply request is wirelessly transmitted from a vehicle, a power supply device embedded in a road contactlessly transmits electric power to the vehicle while the vehicle passes over the road.

### SUMMARY

In a case where the approach of the vehicle to the ground-side device is detected by wireless communication, however, there is a possibility that the alternating current magnetic field cannot be generated at the appropriate timing due to hindrance to the wireless communication by an obstacle or the like. When the transmission-side resonance circuit md the reception-side resonance circuit are misaligned while the mobile body such as a vehicle is passing over the ground-side device, the efficiency of electric power transmission decreases.

The present disclosure provides a contactless power supply system, a position estimation method, a mobile body, and a power supply device in which a relative positional relationship between a transmission-side resonance circuit and a reception-side resonance circuit is accurately detected during contactless electric power transmission of magnetic field resonance coupling between the mobile body and a ground-side device.

A first aspect of the present disclosure relates to a contactless power supply system configured to perform contactless electric power transmission of magnetic field resonance coupling between a ground-side device and a mobile body. The contactless power supply system includes a transmission-side resonance circuit, a reception-side resonance circuit, n alternating current magnetic field generation circuit, mid a magnetic field detector. The transmission-side resonance circuit is configured to transmit electric power. The reception-side resonance circuit is configured to receive the electric power from the transmission-side resonance circuit. Me alternating current magnetic field generation circuit is configured to generate a alternating current magnetic field for detecting a relative positional relationship between the transmission-side resonance circuit and the reception-side resonance circuit. The magnetic field detector is configured to detect the alternating current magnetic field. A frequency of the alternating current magnetic field is different from a resonance frequency of each of the transmission-side resonance circuit and the reception-side resonance circuit.

In the contactless power supply system of the first aspect, the frequency of the alternating current magnetic field may be lower than the resonance frequency.

The contactless power supply system of the first aspect may further include a filter circuit configured to filter m output of the magnetic field detector. The filter circuit may be configured to pass a signal having the frequency of the alternating current magnetic field md attenuate a signal having the resonance frequency.

In the contactless power supply system of the first aspect, the transmission-side resonance circuit and the magnetic field detector may be provided in one of the mobile body and the ground-side device. The reception-side resonance circuit and the alternating current magnetic field generation circuit may be provided in another one of the mobile body and the ground-side device.

In the contactless power supply system of the above configuration, the transmission-side resonance circuit mad the magnetic field detector may be provided in the ground-side device. The reception-side resonance circuit ad the alternating current magnetic field generation circuit may be provided in the mobile body.

In the contactless power supply system of the above configuration, the transmission-side resonance circuit md the magnetic field detector may be provided in the mobile body. The reception-side resonance circuit md the alternating current magnetic field generation circuit may be provided in the ground-side device.

In the contactless power supply system of the first aspect, a plurality of the magnetic field detectors may be provided along a direction perpendicular to a traveling direction of the mobile body.

The contactless power supply system having the configuration described above my further include a position estimator configured to estimate the relative positional relationship between the transmission-side resonance circuit and the reception-side resonance circuit based on an output of the magnetic field detector, and a power supply controller configured to control the contactless electric power transmission based on the relative positional relationship estimated by the position estimator. The power supply controller may be configured to prohibit electric power transmission from the transmission-side resonance circuit to the reception-side resonance circuit when the transmission-side resonance circuit and the reception-side resonance circuit are misaligned in the direction perpendicular to the traveling direction of the mobile body.

The contactless power supply system having the configuration described above may further include a position estimator configured to estimate the relative positional relationship between the transmission-side resonance circuit and the reception-side resonance circuit based on an output of the magnetic field detector, and a power supply controller configured to control the contactless electric power transmission based on the relative positional relationship estimated by the position estimator. A plurality of the transmission-side resonance circuits may be provided along the direction perpendicular to the traveling direction of the mobile body, and the power supply controller may be configured to switch the transmission-side resonance circuit that transmits the electric power to the reception-side resonance circuit based on the relative positional relationship in the direction perpendicular to the traveling direction of the mobile body.

In the contactless power supply system of the first aspect, the alternating current magnetic field may include identification information of the mobile body.

A second aspect of the present disclosure relates to a position estimation method to be applied to a contactless power supply system configured to perform contactless electric power transmission of magnetic field resonance coupling between a ground-side device and a mobile body. The contactless power supply system includes an alternating current magnetic field generation circuit, a magnetic field detector, a transmission-Side resonance circuit, and a reception-side resonance circuit. The position estimation method includes (i) generating a alternating current magnetic field by the alternating current magnetic field generation circuit, (ii) detecting the alternating current magnetic field by the magnetic field detector, and (iii) estimating, based on an output of the magnetic field detector, a relative positional relationship between the transmission-side resonance circuit that transmits electric power and the reception-side resonance circuit that receives the electric power from the transmission-side resonance circuit. A frequency of the alternating current magnetic field is different from a resonance frequency of each of the transmission-side resonance circuit and the reception-side resonance circuit.

A third aspect of the present disclosure relates to a mobile body configured such that electric power is contactlessly transmitted from a ground-side device. The mobile body includes a reception-side resonance circuit and an alternating current magnetic field generation circuit. The reception-side resonance circuit is configured to receive the electric power transmitted from a transmission-side resonance circuit provided in the ground-side device. The alternating current magnetic field generation circuit is configured to generate an alternating current magnetic field for detecting a relative positional relationship between the transmission-side resonance circuit and the reception-side resonance circuit. A frequency of the alternating current magnetic field is different from a resonance frequency of each of the transmission-side resonance circuit and the reception-side resonance circuit.

A fourth aspect of the present disclosure relates to a power supply device configured to perform contactless power supply to a mobile body. The power supply device includes a transmission-side resonance circuit, a magnetic field detector, and a control device. The transmission-side resonance circuit is configured to transmit electric power to a reception-side resonance circuit of the mobile body. The magnetic field detector is configured to detect a magnetic field around the power supply device. The control device is configured to extract an alternating current magnetic field having a specific frequency from an output of the magnetic field detector and detect a relative positional relationship between the transmission-side resonance circuit and the reception-side resonance circuit based on the alternating current magnetic field having the specific frequency. The specific frequency is different from a resonance frequency of each of the transmission-side resonance circuit and the reception-side resonance circuit.

According to the contactless power supply system, the position estimation method, the mobile body, and the power supply device of the present disclosure, the relative positional relationship between the transmission-side resonance circuit and the reception-side resonance circuit can accurately be detected during the contactless electric power transmission of magnetic field resonance coupling between the mobile body and the ground-side device.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram schematically illustrating a configuration of a contactless power supply system according to a first embodiment of the present disclosure;

FIG. 2 is a schematic configuration diagram of a controller of aground-side device that is an example of a power supply device according to the first embodiment of the present disclosure;

FIG. 3 is a schematic configuration diagram of an electronic control unit (ECU) of a vehicle that performs contactless electric power transmission of magnetic field resonance coupling (magnetic field resonance) with the ground-side device;

FIG. 4 is a functional block diagram of a processor of the controller,

FIG. 5 is a flowchart illustrating a control routine of a power supply process according to the first embodiment of the present disclosure:

FIG. 6 is a diagram schematically illustrating a part of a configuration of a contactless power supply system according to a second embodiment of the present disclosure;

FIG. 7 is a diagram illustrating e example of arrangement of magnetic field detectors according to a third embodiment of the present disclosure:

FIG. 8 is a flowchart illustrating a control routine of a power supply process according to the third embodiment of the present disclosure;

FIG. 9 is a diagram illustrating n example of arrangement of magnetic field detectors and transmission-side resonance circuits according to a fourth embodiment of the present disclosure;

FIG. 10 is a flowchart illustrating a control routine of a power supply process according to the fourth embodiment of the present disclosure:

FIG. 11 is a diagram schematically illustrating a configuration of a contactless power supply system according to a fifth embodiment of the present disclosure:

FIG. 12 is a functional block diagram of a processor of n ECU constituting the contactless power supply system according to the fifth embodiment; and

FIG. 13 is a flowchart illustrating a control routine of a power supply process according to the fifth embodiment of the present disclosure.

### DETAILED DESCRIPTION OF EMBODIMENTS

Embodiments of the present disclosure will be described below in detail with reference to the drawings. In the following description, like constituent elements are denoted by like reference numerals.

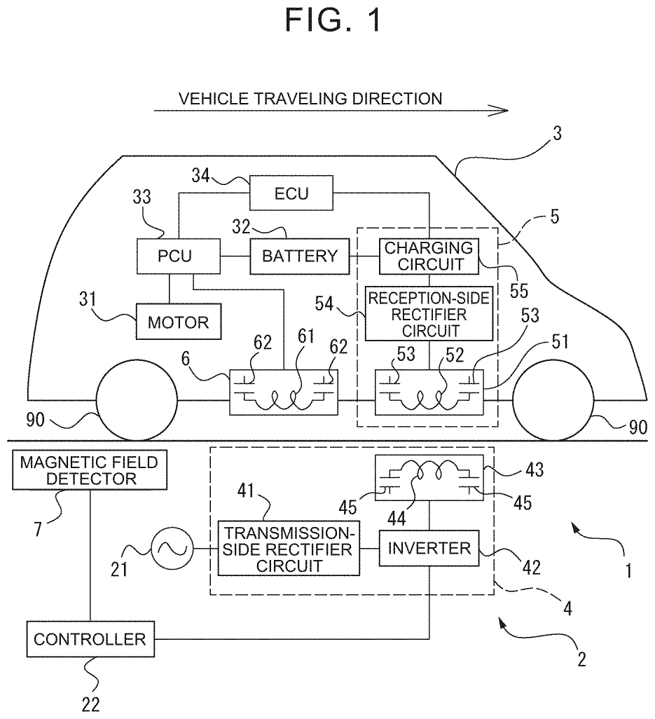

A first embodiment of the present disclosure will be described below with reference to FIGS. 1 to S.

FIG. 1 is a diagram schematically illustrating a configuration of a contactless power supply system 1 according to the first embodiment of the present disclosure. The contactless power supply system 1 performs contactless electric power transmission of magnetic field resonance coupling (magnetic field resonance) between a ground-side device 2 and a vehicle 3. Particularly in the present embodiment, the contactless power supply system 1 performs the contactless electric power transmission between the ground-side device 2 and the vehicle 3 while the vehicle 3 is traveling. The ground-side device 2 is example of a power supply device, and the vehicle 3 is a example of a mobile body. The contactless electric power transmission is also referred to a “contactless power supply”. “wireless electric power transmission”, or “wireless power supply”.

The contactless power supply system 1 includes a power transmission device 4 configured to contactlessly transmit electric power, and a power reception device 5 configured to contactlessly receive the electric power from the power transmission device 4. In the present embodiment, the power transmission device 4 is mounted on the ground-side device 2, and the power reception device 5 is mounted on the vehicle 3. That is, the ground-side device 2 performs contactless power supply to the vehicle 3, and the contactless power supply system 1 contactlessly transmits electric power from the ground-side device 2 to the vehicle 3.

As illustrated in FIG. 1, the ground-side device 2 includes a power supply 21 and a controller 22 in addition to the power transmission device 4. The ground-side device 2 is provided on a road were the vehicle 3 passes, and is, for example, embedded in the ground (under the road surface). At least apart of the ground-side device 2 (for example, the power supply 21 and the controller 22) may be arranged above the road surface.

The power supply 21 is an electric power source of the power transmission device 4 and supplies electric power to the power transmission device 4. Examples of the power supply 21 include a commercial alternating current power supply that supplies single-phase alternating current power. The power supply 21 may be, for example, an alternating current power supply that supplies three-phase alternating current power.

The power transmission device 4 includes a transmission-side rectifier circuit 41, an inverter 42, and a transmission-side resonance circuit 43. In the power transmission device 4, appropriate alternating current power (high-frequency power) is supplied to the transmission-side resonance circuit 43 via the transmission-side rectifier circuit 41 and the inverter 42.

The transmission-side rectifier circuit 41 is electrically connected to the power supply 21 and the inverter 42. The transmission-side rectifier circuit 41 rectifies alternating current power supplied from the power supply 21 to convert the alternating current power into direct current power, and supplies the direct current power to the inverter 42. Examples of the transmission-side rectifier circuit 41 include a alternating current-direct current converter.

The inverter 42 is electrically connected to the transmission-side rectifier circuit 41 and the transmission-side resonance circuit 43. The inverter 42 converts the direct current power supplied from the transmission-side rectifier circuit 41 into alternating current power (high-frequency power) having a frequency higher than that of the alternating current power of the power supply 21, and supplies the high-frequency power to the transmission-side resonance circuit 43.

The transmission-side resonance circuit 43 includes a resonator including a coil 44 and capacitors 45. Various parameters of the coil 44 and the capacitors 45 (outside diameter and bore diameter of the coil 44, number of turns of the coil 44, capacitance of the capacitors 45, etc.) are determined so that the resonance frequency of the transmission-side resonance circuit 43 reaches a predetermined set value. The predetermined set value is, for example, 10 kHz to 100 GHz, preferably 85 kHz defined by the SAE TIR J2954 standard as a frequency band for contactless electric power transmission.

The transmission-side resonance circuit 43 is arranged at the center of a lane where the vehicle 3 passes to position the center of the coil 44 at the center of the lane. When the high-frequency power supplied from the inverter 42 is applied to the transmission-side resonance circuit 43, the transmission-side resonance circuit 43 generates an alternating current magnetic field for transmitting the electric power. The power supply 21 may be a direct current power supply such as a fuel cell or a solar cell. In this case, the transmission-side rectifier circuit 41 may be omitted.

The controller 22 is, for example, a general-purpose computer, and performs various types of control on the ground-side device 2. For example, the controller 22 is electrically connected to the inverter 42 of the power transmission device 4 and controls the inverter 42 to control the electric power transmission by the power transmission device 4.

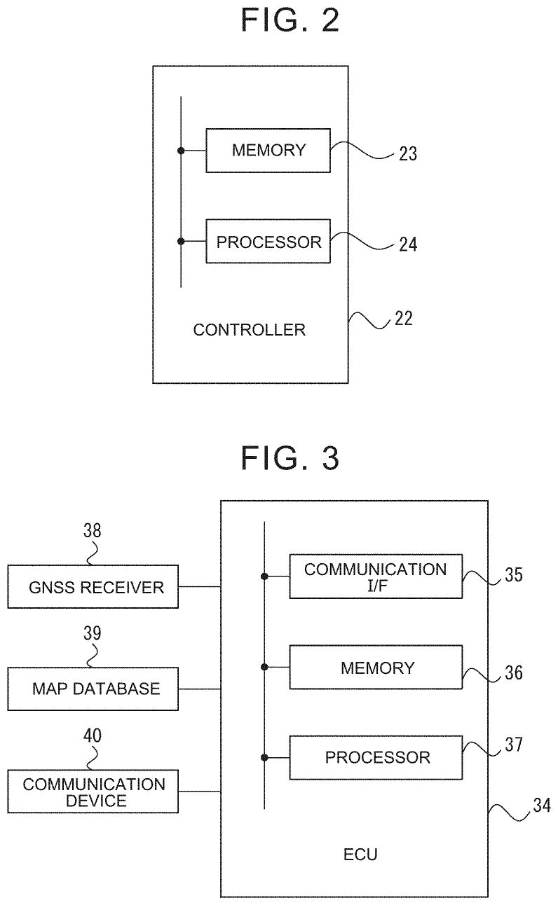

FIG. 2 is a schematic configuration diagram of the controller 22. The controller 22 includes a memory 23 and a processor 24. The memory 23 and the processor 24 are connected to each other via a signal line. The controller 22 may further include, for example, a communication interface that enables communication between the ground-side device 2 and the outside of the ground-side device 2. The controller 22 is an example of a control device of the ground-side device 2.

The memory 23 includes, for example, a volatile semiconductor memory (for example, a random-access memory (RAM)) and a non-volatile semiconductor memory (for example, a read-only memory (ROM)), the memory 23 stores, for example, programs to be executed by the processor 24, and various types of data to be used when various processes are executed by the processor 24.

The processor 24 includes one or more central processing units (CPUs) and their peripheral circuits, and executes various processes. The processor 24 may further include an arithmetic circuit such as a logical operation unit or a numerical operation unit.

As illustrated in FIG. 1, the vehicle 3 includes a motor 31, a battery 32, a power control unit (PCU) 33, and an electronic control unit (ECU) 34 in addition to the power reception device 5. In the present embodiment, the vehicle 3 is a battery electric vehicle (BEV) that is not equipped with an internal combustion engine, and the motor 31 outputs traveling power.

The motor 31 is, for example, an alternating current synchronous motor, and functions e an electric motor and a generator. When the motor 31 functions as the electric motor, the motor 31 is driven by using electric power stored in the battery 32 as a power source. The output of the motor 31 is transmitted to wheels 90 via reducers and axles. When the vehicle 3 is decelerated, the motor 31 is driven by rotation of the wheels 90, and the motor 31 functions a the generator to generate regenerative electric power.

The battery 32 is a rechargeable secondary battery such as a lithium-ion battery or a nickel-metal hydride battery. The battery 32 stores electric power necessary for the vehicle 3 to travel (for example, driving electric power of the motor 31). When the regenerative electric power generated by the motor 31 is supplied to the battery 32, the battery 32 is charged end the charge ratio (state of charge (SOC)) of the battery 32 is recovered. The battery 32 may be charged by an external power supply other than the ground-side device 2 via a charging port provided in the vehicle 3.

The PCU 33 is electrically connected to the battery 32 and the motor 31. The PCU 33 includes an inverter, a boost converter, and a direct current-direct current converter. The inverter converts direct current power supplied from the battery 32 into alternating current power, and supplies the alternating current power to the motor 31. The inverter converts alternating current power (regenerative electric power) generated by the motor 31 into direct current power, and supplies the direct current power to the battery 32. The boost converter boosts a voltage of the battery 32 as needed when the electric power stored in the battery 32 is supplied to the motor 31. The direct current-direct current converter steps down the voltage of the battery 32 when the electric power stored in the battery 32 is supplied to an electronic device such as a headlight.

The power reception device 5 includes a reception-side resonance circuit 51, a reception-side rectifier circuit 54, and a charging circuit 55. The power reception device receives electric power from the power transmission device 4 and supplies the received electric power to the battery 32.

The reception-side resonance circuit 51 is arranged at the bottom of the vehicle 3 to reduce a distance from a road surface. In the present embodiment, the reception-side resonance circuit 51 is arranged at the center of the vehicle 3 in a vehicle width direction, and is arranged between front wheels 90 and rear wheels 90 in a fore-and-aft direction of the vehicle 3.

The reception-side resonance circuit 51 has the same configuration as that of the transmission-side resonance circuit 43, and includes a resonator including a coil 52 and capacitors 53. Various parameters of the coil 52 and the capacitors 53 (outside diameter and bore diameter of the coil 52, number of turns of the coil 52, capacitance of the capacitors 53, etc.) are determined so that the resonance frequency of the reception-side resonance circuit 51 agrees with the resonance frequency of the transmission-side resonance circuit 43. When the amount of deviation between the resonance frequency of the reception-side resonance circuit 51 and the resonance frequency of the transmission-side resonance circuit 43 is small, for example, when the resonance frequency of the reception-side resonance circuit 51 is within a range of ±20% of the resonance frequency of the transmission-side resonance circuit 43, the resonance frequency of the reception-side resonance circuit 51 need not agree with the resonance frequency of the transmission-side resonance circuit 43.

When the alternating current magnetic field is generated in the transmission-side resonance circuit 43 while the reception-side resonance circuit 51 faces the transmission-side resonance circuit 43 as illustrated in FIG. 1, oscillation of the alternating current magnetic field is transmitted to the reception-side resonance circuit 51 that resonates at the same resonance frequency as that of the transmission-side resonance circuit 43. As a result, an induced current flows in the reception-side resonance circuit 51 by electromagnetic induction, and electric power is generated in the reception-side resonance circuit 51 by the induced current. That is, the transmission-side resonance circuit 43 transmits electric power to the reception-side resonance circuit 51, and the reception-side resonance circuit 51 receives the electric power from the transmission-side resonance circuit 43.

The reception-side rectifier circuit 54 is electrically connected to the reception-side resonance circuit 51 and the charging circuit 55. The reception-side rectifier circuit 54 rectifies alternating current power supplied from the reception-side resonance circuit 51 to convert the alternating current power into direct current power, and supplies the direct current power to the charging circuit 55. Examples of the reception-side rectifier circuit 54 include an alternating current-direct current converter.

The charging circuit 55 is electrically connected to the reception-side rectifier circuit 54 and the battery 32. The charging circuit 55 converts the direct current power supplied from the reception-side rectifier circuit 54 into direct current power at a voltage level of the battery 32 and supplies the direct current power to the battery 32. When the electric power transmitted from the power transmission device 4 is supplied to the battery 32 by the power reception device 5, the battery 32 is charged and the SOC of the battery 32 is recovered. Examples of the charging circuit 55 include a direct current-direct current converter.

The ECU 34 performs various types of control on the vehicle 3. For example, the ECU 34 is electrically connected to the charging circuit 55 of the power reception device 5 and controls the charging circuit 55 to control the charging of the battery 32 with the electric power transmitted from the power transmission device 4. The ECU 34 is electrically connected to the PCU 33 and controls the PCU 33 to control the transfer of the electric power between the battery 32 and the motor 31.

FIG. 3 is a schematic configuration diagram of the ECU 34. The ECU 34 includes a communication interface 35, a memory 36, and a processor 37. The communication interface 35, the memory 36, and the processor 37 are connected to each other via a signal line.

The communication interface 35 includes an interface circuit for connecting the ECU 34 to an in-vehicle network conforming to a standard such as a controller area network (CAN).

The memory 36 includes, for example, a volatile semiconductor memory (for example, a RAM) aid a non-volatile semiconductor memory (for example, a ROM). The memory 36 stores, for example, programs to be executed by the processor 37, and various types of data to be used when various processes are executed by the processor 37.

The processor 37 includes one or more central processing units (CPUs) and their peripheral circuits, and executes various processes. The processor 37 may further include an arithmetic circuit such as a logical operation nit or a numerical operation unit.

As illustrated in FIG. 3, the vehicle 3 further includes a global navigation satellite system (GNSS) receiver 38, a nap database 39, aid a communication device 40. The GNSS receiver 38, the map database 39, and the communication device 40 are electrically connected to the ECU 34.

The GNSS receiver 38 detects a current position of the vehicle 3 (for example, a latitude and longitude of the vehicle 3) based on positioning information obtained from a plurality of (for example, three or more) positioning satellites. Specifically, the GNSS receiver 38 captures the positioning satellites and receives radio waves transmitted from the positioning satellites. Then, the GNSS receiver 38 calculates a distance to each positioning satellite based on a difference between a transmission time and a reception time of the radio wave, and detects a current position of the vehicle 3 based on the distance to the positioning satellite and the position of the positioning satellite (orbit information). The output of the GNSS receiver 38, that is, the current position of the vehicle 3 detected by the GNSS receiver 38 is transmitted to the ECU 34.

The global navigation satellite system (GNSS) is a generic term for satellite positioning systems such a the Global Positioning System (GPS) in the United States, the Global Navigation Satellite System (GLONASS) in Russia, Galileo in Europe, the Quasi-Zenith Satellite System (QZSS) in Japan, BeiDou in China, and the Indian Regional Navigation Satellite System (IRNSS) in India. Therefore, the GNSS receiver 38 includes a GPS receiver.

The map database 39 stores map information. The map information includes, for example, position information of an installation area of the ground-side device 2. The ECU 34 acquires the map information from the map database 39. The map database 39 may be provided outside the vehicle 3 (for example, in a server), and the ECU 34 may acquire the map information from the outside of the vehicle 3.

The communication device 40 is a device that enables communication between the vehicle 3 and the outside of the vehicle 3 (for example, a road-to-vehicle communication device or a data communication module (DCM)). The ECU 34 communicates with the outside of the vehicle 3 via the communication device 40.

As described above, the contactless power supply system 1 transmits the electric power from the ground-side device 2 to the vehicle 3 via the alternating current magnetic field generated in the transmission-side resonance circuit 43 of the power transmission device 4. However, constant generation of the alternating current magnetic field for electric power transmission between the ground-side device 2 and the vehicle 3 leads to a waste of electric power. There is also concern about influence of the alternating current magnetic field on electronic devices or the like.

Therefore, it is desirable to generate the alternating current magnetic field for electric power transmission at an appropriate timing % wen the vehicle 3 passes over the ground-side device 2. In a cue where the approach of the vehicle 3 to the ground-side device 2 is detected by wireless communication, however, there is a possibility that the alternating current magnetic field cannot be generated at the appropriate timing due to hindrance to the wireless communication by an obstacle or the like. When the transmission-side resonance circuit 43 and the reception-side resonance circuit 51 are misaligned while the vehicle 3 is passing over the ground-side device 2, the efficiency of electric power transmission decreases.

In the present embodiment, the contactless power supply system 1 includes an alternating current magnetic field generation circuit 6 and a magnetic field detector 7, and detects a relative positional relationship between the transmission-side resonance circuit 43 of the power transmission device 4 and the reception-side resonance circuit 51 of the power reception device 5 by using the alternating current magnetic field generation circuit 6 and the magnetic field detector 7. In the present embodiment, as illustrated in FIG. 1, the alternating current magnetic field generation circuit 6 is provided in the vehicle 3, and the magnetic field detector 7 is provided in the ground-side device 2.

The alternating current magnetic field generation circuit 6 generates an alternating current magnetic field for detecting the relative positional relationship between the transmission-side resonance circuit 43 and the reception-side resonance circuit 51 (hereinafter referred to a “position detecting alternating current magnetic field”). The alternating current magnetic field generation circuit 6 is arranged at the bottom of the vehicle 3 to reduce a distance from a road surface. In the present embodiment, the alternating current magnetic field generation circuit 6 is arranged at the center of the vehicle 3 in the vehicle width direction, and is arranged behind the reception-side resonance circuit 51 in the fore-and-aft direction of the vehicle 3. The alternating current magnetic field generation circuit 6 may be arranged at the same position a that of the reception-side resonance circuit 51 or in front of the reception-side resonance circuit 51 in the fore-mid-aft direction of the vehicle 3.

The alternating current magnetic field generation circuit 6 has the same configuration as those of the transmission-side resonance circuit 43 and the reception-side resonance circuit 51, and includes a resonator including a coil 61 and capacitors 62. Various parameters of the coil 61 aid the capacitors 62 (outside diameter and bore diameter of the coil 61, number of turns of the coil 61, capacitance of the capacitors 62, etc.) are determined so that the resonance frequency of the alternating current magnetic field generation circuit 6 reaches a predetermined set value. The predetermined set value is set to a value different from the resonance frequencies of the transmission-side resonance circuit 43 and the reception-side resonance circuit 51, that is, the resonance frequency of magnetic field resonance coupling.

As illustrated in FIG. 1, the alternating current magnetic field generation circuit 6 is electrically connected to the PCU 33, and the ECU 34 controls the alternating current magnetic field generation circuit 6 via the PCU 33. The inverter of the PCU 33 converts the direct current power supplied from the battery 32 into alternating current power and supplies the alternating current power to the alternating current magnetic field generation circuit 6 based on a command from the ECU 34. When the alternating current power supplied from the PCU 33 is applied to the Alternating current magnetic field generation circuit 6, the alternating current magnetic field generation circuit 6 generates the position detecting alternating current magnetic field. That is, the alternating current magnetic field generation circuit 6 generates the alternating current magnetic field as a position signal of the vehicle 3.

For example, the ECU 34 controls the PCU 33 to generate the position detecting alternating current magnetic field by the alternating current magnetic field generation circuit 6 when the distance between the installation area of the ground-side device 2 and the vehicle 3 is equal to or smaller than a predetermined value. The distance between the installation area of the ground-side device 2 and the vehicle 3 is calculated by, for example, comparing the current position of the vehicle 3 detected by the GNSS receiver 38 and the position of the installation area of the ground-side device 2 stored in the map database 39. When a predetermined signal is received from a road-side unit provided before the ground-side device 2 via the communication device 40, the ECU 34 may control the PCU 33 to generate the position detecting alternating current magnetic field by the alternating current magnetic field generation circuit 6. The ECU 34 may constantly generate a feeble alternating current magnetic field by the alternating current magnetic field generation circuit 6 while the vehicle 3 is traveling. The ECU 34 may control the alternating current magnetic field generation circuit 6 via on inverter provided separately from the PCU 33.

The alternating current magnetic field generated by the alternating current magnetic field generation circuit 6 as the position signal of the vehicle 3 may include identification information of the vehicle 3 (for example, a vehicle identifier (ID)). That is, the vehicle 3 may transmit the identification information of the vehicle 3 to the ground-side device 2 via the alternating current magnetic field in addition to the position signal of the vehicle 3. In this cue, the ECU 34 of the vehicle 3 transmits the position signal and the identification information of the vehicle 3 to the ground-side device 2 by, for example, modulating the alternating current magnetic field based on the identification information of the vehicle 3 when generating the alternating current magnetic field by the alternating current magnetic field generation circuit 6.

The magnetic field detector 7 detects a magnetic field around the ground-side device 2. Examples of the magnetic field detector 7 include a magneto-impedance (MI) sensor. Driving electric power of the magnetic field detector 7 is supplied to the magnetic field detector 7 from, for example, the power supply 21 via a drive circuit. The magnetic field detector 7 may be a Hall sensor, a magneto-resistive (MR) sensor, or the like.

The magnetic field detector 7 is arranged before the transmission-side resonance circuit 43 of the power transmission device 4 in the traveling direction of the vehicle 3 on a road provided with the power transmission device 4, and is arranged at the center of a lane where the vehicle 3 passes. The magnetic field detector 7 is arranged in the ground (below a road surface) or above the road surface. When the position detecting alternating current magnetic field is generated from the vehicle 3 around the magnetic field detector 7, the magnetic field detector 7 detects the position detecting alternating current magnetic field.

The magnetic field detector 7 is electrically connected to the controller 22, and the output of the magnetic field detector 7 is transmitted to the controller 22. In the present embodiment, the contactless power supply system 1 includes the controller 22 and the controller 22 controls the contactless power supply between the ground-side device 2 and the vehicle 3.

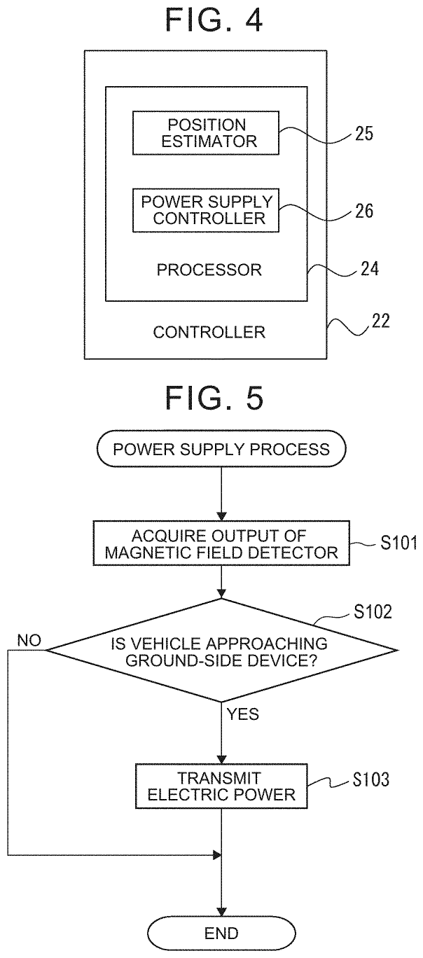

FIG. 4 is a functional block diagram of the processor 24 of the controller 22. In the present embodiment, the processor 24 includes a position estimator 25 and a power supply controller 26. The position estimator 25 and the power supply controller 26 are functional modules implemented by the processor 24 of the controller 22 executing a computer program stored in the memory 23 of the controller 22. The position estimator 25 and the power supply controller 26 may be implemented by a dedicated arithmetic circuit provided in the processor 24.

The position estimator 25 estimates the relative positional relationship between the transmission-side resonance circuit 43 and the reception-side resonance circuit 51 based on the output of the magnetic field detector 7. Specifically, the position estimator extracts an alternating current magnetic field of a specific frequency from the output of the magnetic field detector 7, and estimates the relative positional relationship between the transmission-side resonance circuit 43 and the reception-side resonance circuit 51 based on the extracted alternating current magnetic field of the specific frequency. The specific frequency is a frequency of the AC magnetic field generated from the vehicle 3 as the position signal, and corresponds to a frequency of the alternating current magnetic field to be detected. That is, the position estimator 25 estimates the relative positional relationship between the transmission-side resonance circuit 43 and the reception-side resonance circuit 51 by detecting the position detecting alternating current magnetic field generated from the alternating current magnetic field generation circuit 6.

In the present embodiment, the influence of obstacles in the transmission and reception of signals can be reduced by using the alternating current magnetic field a the position detecting signal. Even when a stationary magnetic field (direct current magnetic field) is generated by a metal or the like present around the ground-side device 2, it is easy to distinguish the stationary magnetic field and the position detecting signal (alternating current magnetic field).

In the present embodiment, the frequency of the position detecting alternating current magnetic field is different from the resonance frequencies of the transmission-side resonance circuit 43 and the reception-side resonance circuit 51. Therefore, it is easy to distinguish the alternating current magnetic field generated in the transmission-side resonance circuit 43 for electric power transmission and the alternating current magnetic field generated in the alternating current magnetic field generation circuit 6 for position detection. By using the alternating current magnetic field having the frequency different from that of the alternating current magnetic field for electric power transmission a the position detecting signal, the relative positional relationship between the transmission-side resonance circuit 43 and the reception-side resonance circuit 51 can be detected accurately.

The frequency of the position detecting alternating current magnetic field is preferably set to a value lower than the resonance frequencies of the transmission-side resonance circuit 43 and the reception-side resonance circuit 51. Thus, the position detecting alternating current magnetic field can be generated more easily. For example, when the resonance frequencies of the transmission-side resonance circuit 43 and the reception-side resonance circuit 51 are 85 kHz, the frequency of the position detecting alternating current magnetic field is set to 50 Hz to 50 kHz, for example, 1 kHz.

In the present embodiment, the transmission-side resonance circuit 43 and the magnetic field detector 7 are provided in the ground-side device 2, and the reception-side resonance circuit 51 and the alternating current magnetic field generation circuit 6 are provided in the vehicle 3. That is, the transmission-side resonance circuit 43 and the magnetic field detector 7 are provided in one of the vehicle 3 and the ground-side device 2, and the reception-side resonance circuit 51 and the alternating current magnetic field generation circuit 6 are provided in the other of the vehicle 3 and the ground-side device 2. In this case, the source of the electric power transmission alternating current magnetic field and the source of the position detecting alternating current magnetic field are different. Therefore, the temporal change in the signal strength detected by the magnetic field detector 7 differs between the position detecting alternating current magnetic field and the electric power transmission alternating current magnetic field. As a result, the position detecting alternating current magnetic field and the electric power transmission alternating current magnetic field can be distinguished more easily, and furthermore, the relative positional relationship between the transmission-side resonance circuit 43 and the reception-side resonance circuit 51 can be detected more accurately.

When the alternating current magnetic field generated by the alternating current magnetic field generation circuit 6 includes the identification information of the vehicle 3, the position estimator 25 acquires the identification information of the vehicle 3 from the output of the magnetic field detector 7. Thus, the vehicle 3 to be supplied with electric power can be identified. As a result, the vehicle 3 can easily be, for example, billed for a power supply fee.

The power supply controller 26 controls the contactless electric power transmission between the ground-side device 2 and the vehicle 3 based on the relative positional relationship between the transmission-side resonance circuit 43 and the reception-side resonance circuit 51 estimated by the position estimator 25. That is, the power supply controller 26 controls the electric power transmission from the transmission-side resonance circuit 43 of the power transmission device 4 to the reception-side resonance circuit 51 of the power reception device 5 based on the estimation result from the position estimator 25. For example, the power supply controller 26 starts the electric power transmission from the transmission-side resonance circuit 43 to the reception-side resonance circuit 51 when the position estimator 25 detects that the vehicle 3 including the reception-side resonance circuit 51 is approaching the ground-side device 2.

The control flow described above will be described below with reference to a flowchart of FIG. 5. FIG. 5 is a flowchart illustrating a control routine of a power supply process according to the first embodiment of the present disclosure. This control routine is repeatedly executed by the processor 24 of the controller 22.

In Step S101, the position estimator 25 first acquires an output of the magnetic field detector 7.

In Step S102, the position estimator 25 determines, based on the output of the magnetic field detector 7, whether the vehicle 3 is approaching the ground-side device 2, that is, whether the reception-side resonance circuit 51 is approaching the transmission-side resonance circuit 43. For example, the position estimator 25 performs frequency analysis on the output of the magnetic field detector 7 to extract a frequency component of the position detecting alternating current magnetic field, and determines that the vehicle 3 is approaching the ground-side device 2 when the value (peak value) of the extracted frequency component is equal to or larger than a predetermined value. Examples of the method for the frequency analysis include Fourier transform.

When determination is made in Step S102 that the vehicle 3 is not approaching the ground-side device 2, this control routine is terminated. When determination is made in Step S102 that the vehicle 3 is approaching the ground-side device 2, this control routine proceeds to Step S103.

In Step S103, the power supply controller 26 transmits electric power from the ground-side device 2 to the vehicle 3. Specifically, the power supply controller 26 controls the inverter 42 of the power transmission device 4 to supply high-frequency power to the transmission-side resonance circuit 43, thereby transmitting the electric power from the transmission-side resonance circuit 43 to the reception-side resonance circuit 51.

For example, the power supply controller 26 transmits the electric power from the transmission-side resonance circuit 43 to the reception-side resonance circuit 51 for a predetermined period. The predetermined period is determined in advance in consideration of a period for the vehicle 3 to pass over the ground-side device 2. The power supply controller 26 may stop the electric power transmission from the transmission-side resonance circuit 43 to the reception-side resonance circuit 51 when the passage of the vehicle 3 over the ground-side device 2 is detected. In this case, for example, the magnetic field detectors 7 are provided in front of and behind the transmission-side resonance circuit 43 in the traveling direction of the vehicle 3, and the passage of the vehicle 3 over the ground-side device 2 is detected based on the output of the magnetic field detector 7 in front of the transmission-side resonance circuit 43. The passage of the vehicle 3 may be detected by, for example, road-to-vehicle communication between the vehicle 3 and a road-side unit. After Step S103, this control routine is terminated.

Next, a second embodiment of the present disclosure will be described. The configuration and control of a contactless power supply system according to the second embodiment are basically the same as the configuration and control of the contactless power supply system according to the first embodiment except for points described below. Therefore, the second embodiment of the present disclosure will be described below focusing on the differences from the first embodiment.

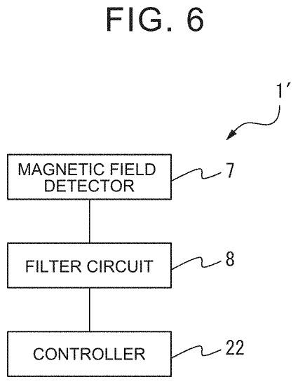

FIG. 6 is a diagram schematically illustrating a part of a configuration of a contactless power supply system 1′ according to the second embodiment of the present disclosure. In the second embodiment, the contactless power supply system 1′ further includes a filter circuit 8 that filters the output of the magnetic field detector 7.

The filter circuit 8 is provided between the magnetic field detector 7 and the controller 22 in the ground-side device 2, and is electrically connected to the magnetic field detector 7 and the controller 22. The filter circuit 8 passes a signal having the frequency of the position detecting alternating current magnetic field and attenuates a signal having the resonance frequency of each of the transmission-side resonance circuit 43 and the reception-side resonance circuit 51.

The position estimator 25 of the controller 22 acquires the output of the magnetic field detector 7 filtered by the filter circuit 8, that is, the output of the magnetic field detector 7 corresponding to the frequency component of the position detecting alternating current magnetic field. Then, the position estimator 25 estimates the relative positional relationship between the transmission-side resonance circuit 43 and the reception-side resonance circuit 51 based on the filtered output of the magnetic field detector 7. Therefore, in the second embodiment, the frequency analysis for the magnetic field detector 7 is omitted or simplified, thereby reducing the calculation load on the controller 22 for position detection.

When the frequency of the position detecting alternating current magnetic field is higher than the resonance frequencies of the transmission-side resonance circuit 43 and the reception-side resonance circuit 51, for example, a high-pass filter (HPF) is used a the filter circuit 8. When the frequency of the position detecting alternating current magnetic field is lower than the resonance frequencies of the transmission-side resonance circuit 43 and the reception-side resonance circuit 51, for example, a low-pass filter (LPF) is used as the filter circuit 8, the filter circuit 8 may be a bandpass filter (BPF) that passes only signals in a specific frequency band that includes the frequency of the position detecting alternating current magnetic field and does not include the frequency of the electric power transmission alternating current magnetic field. Thus, the frequency component of the position detecting alternating current magnetic field can be extracted more accurately from the output of the magnetic field detector 7.

Also in the second embodiment, the control routine of FIG. 5 is executed. In Step S101, the position estimator 25 acquires the output of the magnetic field detector 7 filtered by the filter circuit 8. In Step S102, the position estimator 25 determines whether the vehicle 3 is approaching the ground-side device 2 based on the filtered output of the magnetic field detector 7.

Next, a third embodiment of the present disclosure will be described. The configuration and control of a contactless power supply system according to the third embodiment are basically the same as the configuration and control of the contactless power supply system according to the first embodiment except for points described below. Therefore, the third embodiment of the present disclosure will be described below focusing on the differences from the first embodiment.

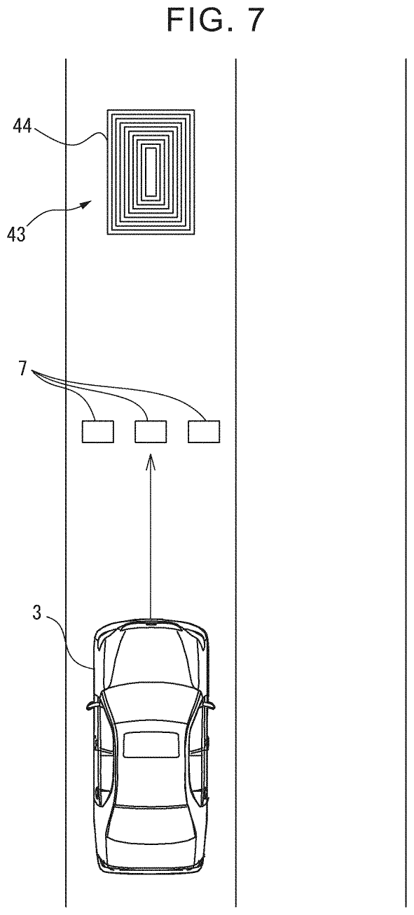

FIG. 7 is a diagram illustrating an example of arrangement of the magnetic field detectors 7 according to the third embodiment of the present disclosure. In the third embodiment, a plurality of magnetic field detectors 7 is provided along a direction perpendicular to the traveling direction of the vehicle 3. That is, the contactless power supply system 1 includes the plurality of magnetic field detectors 7, and the magnetic field detectors 7 are provided in the ground-side device 2. The magnetic field detectors 7 are spaced away from each other along the direction perpendicular to the traveling direction of the vehicle 3. For example, the magnetic field detectors 7 are arranged at equal intervals along the direction perpendicular to the traveling direction of the vehicle 3.

As described above, the reception-side resonance circuit 51 and the alternating current magnetic field generation circuit 6 provided in the vehicle 3 are arranged at the center of the vehicle 3 in the vehicle width direction, and the transmission-side resonance circuit 43 is arranged at the center of a lane where the vehicle 3 passes to position the center of the coil 44 at the center of the lane. Therefore, one of the magnetic field detectors 7 is arranged at the center of the elsewhere the vehicle 3 passes. Thus, one of the magnetic field detectors 7 is arranged at the same position as that of the transmission-side resonance circuit 43 in the direction perpendicular to the traveling direction of the vehicle 3. In the example of FIG. 7, the magnetic field detector 7 is arranged at the center of the lane, and the magnetic field detectors 7 are arranged on the right and left sides of the central magnetic field detector 7. Therefore, a total of three magnetic field detectors 7 are arranged at equal intervals.

When the reception-side resonance circuit 51 and the transmission-side resonance circuit 43 are misaligned while the vehicle 3 is passing over the ground-side device 2, that is, when the vehicle 3 is traveling with displacement from the center of the lane, the efficiency of electric power transmission from the transmission-side resonance circuit 43 to the reception-side resonance circuit 51 decreases. In the third embodiment, the power supply controller 26 prohibits the electric power transmission from the transmission-side resonance circuit 43 to the reception-side resonance circuit 51 when the reception-side resonance circuit 51 and the transmission-side resonance circuit 43 are misaligned in the direction perpendicular to the traveling direction of the vehicle 3. As a result, it is possible to suppress the transmission of electric power while the efficiency of electric power transmission decreases, and furthermore, reduce the waste of power consumption in the power transmission device 4.

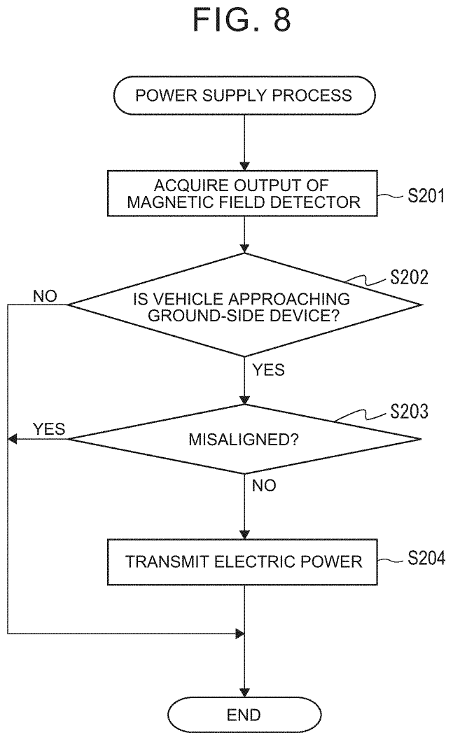

FIG. 8 is a flowchart illustrating a control routine of a power supply process according to the third embodiment of the present disclosure. This control routine is repeatedly executed by the processor 24 of the controller 22.

In Step S201, the position estimator 25 first acquires outputs of the magnetic field detectors 7.

In Step S202, the position estimator 25 determines whether the vehicle 3 is approaching the ground-side device 2 similarly to Step S102 in FIG. 5. For example, the position estimator 25 determines that the vehicle 3 is approaching the ground-side device 2 when the value (peak value) of the frequency component of the position detecting alternating current magnetic field in the output of at least one of the magnetic field detectors 7 is equal to or larger than the predetermined value.

When determination is made in Step S202 that the vehicle 3 is not approaching the ground-side device 2, this control routine is terminated. When determination is made in Step S202 that the vehicle 3 is approaching the ground-side device 2, this control routine proceeds to Step S203.

In Step S203, the position estimator 25 determines whether the reception-side resonance circuit 51 and the transmission-side resonance circuit 43 are misaligned in the direction perpendicular to the traveling direction of the vehicle 3. For example, the position estimator 25 determines that the reception-side resonance circuit 51 and the transmission-side resonance circuit 43 are misaligned when the output of the magnetic field detector 7 arranged at the center of the lane is not maximum among the outputs of the magnetic field detectors 7, that is, when the output of the magnetic field detector 7 arranged at a position other than the center of the lane is maximum. The position estimator 25 may determine that the reception-side resonance circuit 51 and the transmission-side resonance circuit 43 are misaligned when the output of the magnetic field detector 7 arranged on the outermost side in a width direction of the lane is maximum. The position estimator 25 may calculate n amount of misalignment between the reception-side resonance circuit 51 and the transmission-side resonance circuit 43 based on the outputs of the magnetic field detectors 7, and determine that the reception-side resonance circuit 51 and the transmission-side resonance circuit 43 are misaligned when the calculated misalignment amount is equal to or larger than a predetermined value.

When determination is made in Step S203 that the reception-side resonance circuit 31 and the transmission-side resonance circuit 43 we misaligned, this control routine is terminated. That is, the electric power transmission from the transmission-side resonance circuit 43 to the reception-side resonance circuit 51 is prohibited when the vehicle 3 passes over the ground-side device 2.

When determination is made in Step S203 that the reception-side resonance circuit 51 and the transmission-side resonance circuit 43 are not misaligned, this control routine proceeds to Step S204. In Step S204, the power supply controller 26 transmits electric power from the ground-side device 2 to the vehicle 3 similarly to Step S103 in FIG. 5. After Step S204, this control routine is terminated.

Next, a fourth embodiment of the present disclosure will be described. The configuration and control of a contactless power supply system according to the fourth embodiment we basically the same as the configuration and control of the contactless power supply system according to the first embodiment except for points described below. Therefore, the fourth embodiment of the present disclosure will be described below focusing on the differences from the first embodiment.

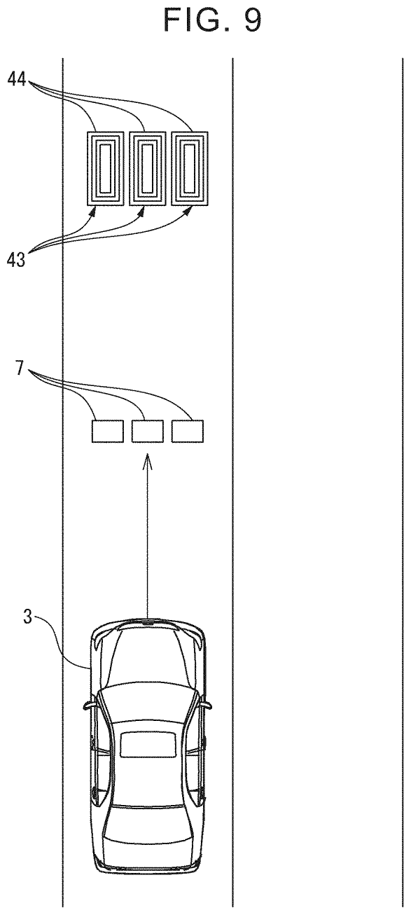

FIG. 9 is a diagram illustrating an example of arrangement of the magnetic field detectors 7 and the transmission-side resonance circuits 43 according to the fourth embodiment of the present disclosure. In the fourth embodiment, the magnetic field detectors 7 are provided along the direction perpendicular to the traveling direction of the vehicle 3 similarly to the third embodiment.

In the fourth embodiment, a plurality of transmission-side resonance circuits 43 of the power transmission device 4 as well as the magnetic field detectors 7 is provided along the direction perpendicular to the traveling direction of the vehicle 3. That is, the contactless power supply system 1 includes the plurality of transmission-side resonance circuits 43, and the transmission-side resonance circuits 43 are provided in the ground-side device 2. The transmission-side resonance circuits 43 are spaced away from each other along the direction perpendicular to the traveling direction of the vehicle 3. For example, the transmission-side resonance circuits 43 are arranged at equal intervals along the direction perpendicular to the traveling direction of the vehicle 3.

As described above, the reception-side resonance circuit 51 provided in the vehicle 3 is arranged at the center of the vehicle 3 in the vehicle width direction. Therefore, one of the transmission-side resonance circuits 43 is arranged at the center of a lane of the road where the vehicle 3 passes. In the example of FIG. 9, the transmission-side resonance circuit 43 is arranged at the center of the lane, ad the transmission-side resonance circuits 43 are arranged on the right and left sides of the central transmission-side resonance circuit 43. Therefore, a total of three transmission-side resonance circuits 43 are arranged at equal intervals. That is, the number of transmission-side resonance circuits 43 is equal to the number of magnetic field detectors 7.

When the plurality of transmission-side resonance circuits 43 is arranged in the vehicle width direction, the transmission-side resonance circuit 43 closest to the reception-side resonance circuit 31 provided in the vehicle 3 differs depending on a lateral position of the vehicle 3. For example, when the vehicle 3 is traveling with displacement to the right in the traveling direction, the right transmission-side resonance circuit 43 is closest to the reception-side resonance circuit 51. When the vehicle 3 is traveling with displacement to the left in the traveling direction, the left transmission-side resonance circuit 43 is closest to the reception-side resonance circuit 51.

In the fourth embodiment, the power supply controller 26 switches the transmission-side resonance circuit 43 that transmits electric power to the reception-side resonance circuit 51 based on the relative positional relationship between the transmission-side resonance circuit 43 and the reception-side resonance circuit 51 in the direction perpendicular to the traveling direction of the vehicle 3. As a result, it is possible to suppress the decrease in the efficiency of electric power transmission due to the misalignment between the reception-side resonance circuit 51 and the transmission-side resonance circuit 43, and furthermore, reduce the waste of power consumption in the power transmission device 4.

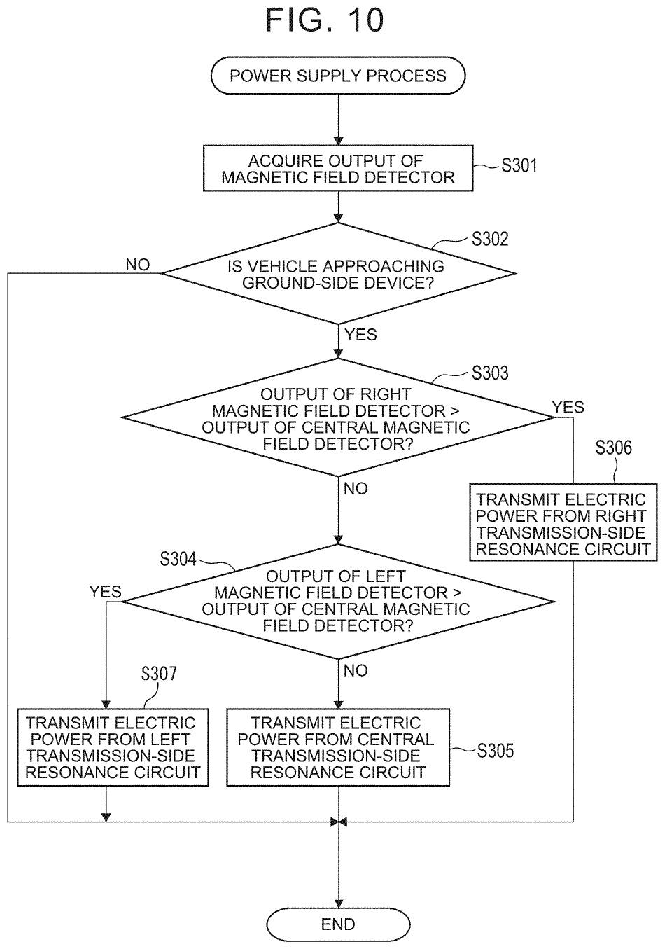

FIG. 10 is a flowchart illustrating a control routine of a power supply process according to the fourth embodiment of the present disclosure. This control routine is repeatedly executed by the processor 24 of the controller 22.

Steps S301 and S302 are executed similarly to Steps S201 and S202 in FIG. 8. When determination is made in Step S302 than the vehicle 3 is approaching the ground-side device 2, this control routine proceeds to Step S303.

In Step S303, the position estimator 25 determines whether the output of the magnetic field detector 7 on the right side in the traveling direction of the vehicle 3 is larger than the output of the magnetic field detector 7 at the center of the lane in terms of the frequency component of the position detecting alternating current magnetic field. When determination is made that the output of the right magnetic field detector 7 is equal to or smaller than the output of the central magnetic field detector 7, this control routine proceeds to Step S304.

In Step S304, the position estimator 25 determines whether the output of the magnetic field detector 7 on the left side in the traveling direction of the vehicle 3 is larger than the output of the magnetic field detector 7 at the center of the lane in terms of the frequency component of the position detecting alternating current magnetic field. When determination is made that the output of the left magnetic field detector 7 is equal to or smaller than the output of the central magnetic field detector 7, that is, when the output of the central magnetic field detector 7 is maximum, the position estimator 25 determines that the vehicle 3 is not displaced and this control routine proceeds to Step S305.

In Step S305, the power supply controller 26 transmits electric power from the transmission-side resonance circuit 43 at the center of the lane to the reception-side resonance circuit 51. Specifically, the power supply controller 26 controls the inverter 42 of the power transmission device 4 to supply high-frequency power to the transmission-side resonance circuit 43 at the center of the lane. After Step S305, this control routine is terminated.

When determination is made in Step S303 that the output of the right magnetic field detector 7 is larger than the output of the central magnetic field detector 7, the position estimator 25 determines that the vehicle 3 is displaced to the right in the traveling direction and this control routine proceeds to Step S306. In Step S306, the power supply controller 26 transmits electric power from the transmission-side resonance circuit 43 on the right side in the traveling direction of the vehicle 3 to the reception-side resonance circuit 51. Specifically, the power supply controller 26 controls the inverter 42 of the power transmission device 4 to supply high-frequency power to the right transmission-side resonance circuit 43. After Step S306, this control routine is terminated.

When determination is made in Step S304 that the output of the left magnetic field detector 7 is larger dh the output of the central magnetic field detector 7, the position estimator 25 determines that the vehicle 3 is displaced to the left in the traveling direction and this control routine proceeds to Step S307. In Step S307, the power supply controller 26 transmits electric power from the transmission-side resonance circuit 43 on the left side in the traveling direction of the vehicle 3 to the reception-side resonance circuit 51. Specifically, the power supply controller 26 controls the inverter 42 of the power transmission device 4 to supply high-frequency power to the left transmission-side resonance circuit 43. After Step S307, this control routine is terminated.

In Step S305, the power supply controller 26 may transmit the electric power from all the transmission-side resonance circuits 43 to the reception-side resonance circuit 51. In Step S306, the power supply controller 26 may transmit the electric power to the reception-side resonance circuit 31 from the transmission-side resonance circuit 43 on the right side in the traveling direction of the vehicle 3 and the transmission-side resonance circuit 43 at the center of the lane. In Step S307, the power supply controller 26 may transmit the electric power to the reception-side resonance circuit 51 from the transmission-side resonance circuit 43 on the left side in the traveling direction of the vehicle 3 and the transmission-side resonance circuit 43 at the center of the lane.

Next, a fifth embodiment of the present disclosure will be described. The configuration and control of a contactless power supply system according to the fifth embodiment are basically the same as the configuration and control of the contactless power supply system according to the first embodiment except for points described below. Therefore, the fifth embodiment of the present disclosure will be described below focusing on the differences from the first embodiment.

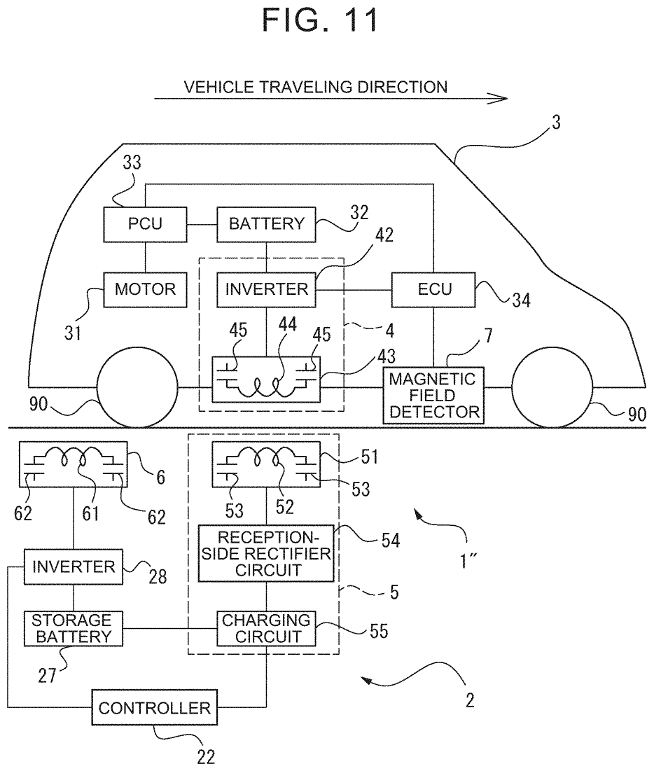

FIG. 11 is a diagram schematically illustrating a configuration of a contactless power supply system 1″ according to the fifth embodiment of the present disclosure. As described above, the batten 32 of the vehicle 3 can be charged with the regenerative electric power generated by the motor 31. When the SOC of the battery 32 is high, however, the regenerative electric power cannot be supplied to the battery 32. When the SOC of the battery 32 is kept high, deterioration of the battery 32 is advanced. Therefore, there is a need to reduce the SOC of the battery 32 while the vehicle 3 is traveling.

In the fifth embodiment, the power transmission device 4 is mounted on the vehicle 3 and the power reception device 5 is mounted on the ground-side device 2 unlike the first embodiment. That is, the contactless power supply system 1″ contactlessly transmits the electric power from the vehicle 3 to the ground-side device 2 while the vehicle 3 is traveling.

In the fifth embodiment, the power transmission device 4 includes the inverter 42 and the transmission-side resonance circuit 43. The battery 32 is used as the electric power source of the power transmission device 4, and the electric power of the battery 32 is consumed by electric power transmission from the vehicle 3 to the ground-side device 2.

The inverter 42 is electrically connected to the battery 32 and the transmission-side resonance circuit 43. The inverter 42 converts the direct current power supplied from the battery 32 into high-frequency power, and supplies the high-frequency power to the transmission-side resonance circuit 43. When the high-frequency power supplied from the inverter 42 is applied to the transmission-side resonance circuit 43, the transmission-side resonance circuit 43 generates an alternating current magnetic field for transmitting the electric power. The ECU 34 is electrically connected to the inverter 42 of the power transmission device 4 and controls the inverter 42 to control the electric power transmission by the power transmission device 4. The inverter 42 may be omitted and the PCU 33 may electrically be connected to the transmission-side resonance circuit 43 to function as an inverter of the power transmission device 4.

The power reception device 5 includes the reception-side resonance circuit 51, the reception-side rectifier circuit 54, and the charging circuit 55 similarly to the first embodiment. The ground-side device 2 includes a storage battery 27, and the electric power transmitted from the power transmission device 4 to the power reception device 5 is supplied to the storage battery 27. The storage battery 27 is a rechargeable secondary battery such as a lithium-ion battery or a nickel-metal hydride battery.

When the alternating current magnetic field is generated in the transmission-side resonance circuit 43 while the reception-side resonance circuit 51 faces the transmission-side resonance circuit 43 illustrated in FIG. 11, oscillation of the alternating current magnetic field is transmitted to the reception-side resonance circuit 51 that resonates at the same resonance frequency as that of the transmission-side resonance circuit 43. As a result, n induced current flows in the reception-side resonance circuit 51 by electromagnetic induction, and electric power is generated in the reception-side resonance circuit 51 by the induced current. That is, the transmission-side resonance circuit 43 transmits electric power to the reception-side resonance circuit 51, and the reception-side resonance circuit 51 receives the electric power from the transmission-side resonance circuit 43.

The charging circuit 55 is electrically connected to the reception-side rectifier circuit 54 and the storage battery 27. The charging circuit 55 converts the direct current power supplied from the reception-side rectifier circuit 54 into direct current power at a voltage level of the storage battery 27 and supplies the direct current power to the storage battery 27. When the electric power transmitted from the power transmission device 4 is supplied to the storage battery 27 by the power reception device 5, the storage battery 27 is charged.

In the fifth embodiment, the alternating current magnetic field generation circuit 6 is provided in the ground-side device 2, and the magnetic field detector 7 is provided in the vehicle 3. The alternating current magnetic field generation circuit 6 is arranged at the center of the lane where the vehicle 3 passes, and is arranged before the reception-side resonance circuit 51 in the traveling direction of the vehicle 3. The alternating current magnetic field generation circuit 6 may be arranged at the same position as that of the reception-side resonance circuit 51 or in front of the reception-side resonance circuit 51 in the traveling direction of the vehicle 3.

The ground-side device 2 includes an inverter 28, and the alternating current magnetic field generation circuit 6 generates the position detecting alternating current magnetic field by using electric power supplied from the inverter 28. The inverter 28 is electrically connected to the storage battery 27 and the alternating current magnetic field generation circuit 6. The controller 22 is electrically connected to the inverter 28 and controls the alternating current magnetic field generation circuit 6 via the inverter 28.

The inverter 28 converts the direct current power supplied from the storage battery 27 into alternating current power and supplies the alternating current power to the alternating current magnetic field generation circuit 6 based on a command from the controller 22. When the alternating current power supplied from the inverter 28 is applied to the alternating current magnetic field generation circuit 6, the alternating current magnetic field generation circuit 6 generates the position detecting alternating current magnetic field.

For example, when a road-side unit provided before the ground-side device 2 detects the vehicle 3 and the controller 22 receives a signal from the road-side unit, the controller 22 controls the inverter 28 to generate the position detecting alternating current magnetic field by the alternating current magnetic field generation circuit 6. The controller 22 may constantly generate a feeble alternating current magnetic field by the alternating current magnetic field generation circuit 6 in a predetermined time frame (for example, a time frame other than nighttime) or all day long.

As illustrated in FIG. 11, the magnetic field detector 7 is arranged in front of the transmission-side resonance circuit 43 in the vehicle 3. The magnetic field detector 7 is electrically connected to the ECU 34, and the output of the magnetic field detector 7 is transmitted to the ECU 34. In the fifth embodiment, the contactless power supply system 1″ includes the ECU 34, and the ECU 34 controls the contactless power supply between the ground-side device 2 and the vehicle 3.

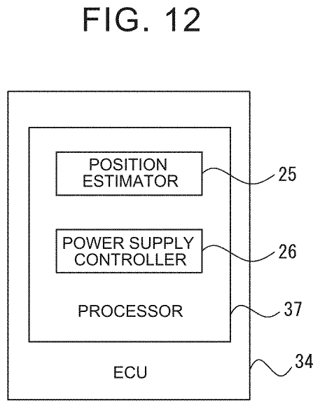

FIG. 12 is a functional block diagram of the processor 37 of the ECU 34. In the present embodiment, the processor 37 includes the position estimator 23 and the power supply controller 26. The position estimator 25 and the power supply controller 26 are functional modules implemented by the processor 37 of the ECU 34 executing a computer program stored in the memory 36 of the ECU 34. The position estimator 25 and the power supply controller 26 may be implemented by a dedicated arithmetic circuit provided in the processor 37.

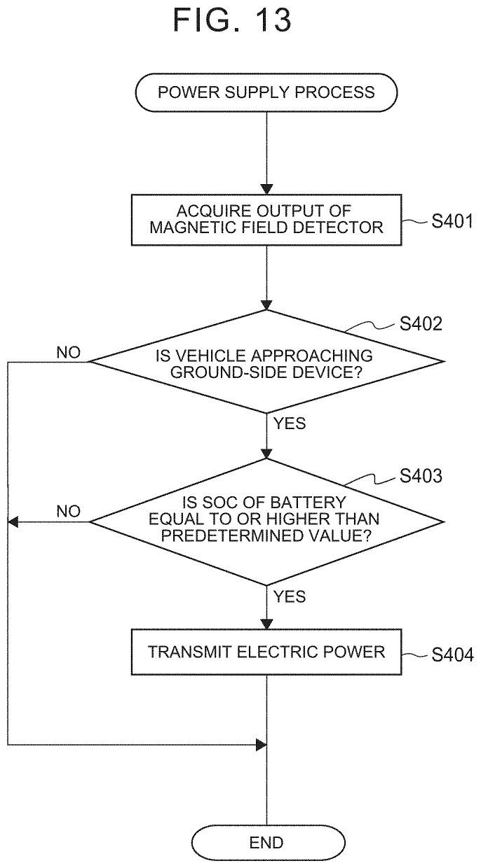

FIG. 13 is a flowchart illustrating a control routine of a power supply process according to the fifth embodiment of the present disclosure. This control routine is repeatedly executed by the processor 37 of the ECU 34.

Steps S401 and S402 are executed similarly to Steps S101 and S102 in FIG. 5. When determination is made in Step S402 that the vehicle 3 is approaching the ground-side device 2, this control routine proceeds to Step S403.

In Step S403, the power supply controller 26 determines whether the SOC of the battery 32 of the vehicle 3 is equal to or higher than a predetermined value. The predetermined value is set to, for example, an upper limit of a value at which the regenerative electric power can be collected.

The SOC of the battery 32 is calculated by a known method. For example, a battery sensor for detecting state parameters of the battery 32 is provided in the battery 32, and the power supply controller 26 calculates the SOC of the battery 32 based on a voltage and temperature of the battery 32 detected by the battery sensor. The power supply controller 26 may calculate the SOC of the battery 32 by integrating input and output currents of the battery 32 detected by the battery sensor. The power supply controller 26 may calculate the SOC of the battery 32 by using a state estimation method such as a Kalman filter.

When determination is made in Step S403 that the SOC of the battery 32 is lower than the predetermined value, this control routine is terminated. When determination is made in Step S403 that the SOC of the battery 32 is equal to or higher than the predetermined value, this control routine proceeds to Step S404.

In Step S404, the power supply controller 26 transmits electric power from the vehicle 3 to the ground-side device 2. Specifically, similarly to Step S103 in FIG. 5, the power supply controller 26 controls the inverter 42 of the power transmission device 4 to supply high-frequency power to the transmission-side resonance circuit 43, thereby transmitting the electric power from the transmission-side resonance circuit 43 to the reception-side resonance circuit 51. After Step S404, this control routine is terminated.

Next, other embodiments of the present disclosure will be described. Although the preferred embodiments of the present disclosure have been described above, the present disclosure is not limited to these embodiments, and various revisions and modifications may be made within the scope of the claims. For example, the configurations of the resonators of the transmission-side resonance circuit 43, the reception-side resonance circuit 51, and the alternating current magnetic field generation circuit 6 are only illustrative. For example, the numbers of capacitors 45, 53, and 62 may be one. Since the alternating current magnetic field generation circuit 6 that generates the position detecting alternating current magnetic field need not use the magnetic field resonance coupling, the capacitors 62 may be omitted.

The vehicle 3 may be a hybrid electric vehicle (HEV) or a plug-in hybrid electric vehicle (PHEV) including an internal combustion engine and a motor as traveling power sources. The vehicle 3 may be an autonomous driving vehicle in which at least a part of acceleration, steering, and deceleration (braking) of the vehicle 3 is controlled autonomously. The mobile body that transfers electric power with the ground-side device 2 may be a commercial vehicle such as a bus or a truck, an automated guided vehicle (AGV), a drone, or the like.

In the first embodiment illustrated in FIG. 1, the alternating current magnetic field generation circuit 6 may be provided in the ground-side device 2, and the magnetic field detector 7 and the position estimator 25 may be provided in the vehicle 3. In this case, for example, the relative positional relationship between the transmission-side resonance circuit 43 and the reception-side resonance circuit 51 estimated by the position estimator 25 based on the output of the magnetic field detector 7 is presented to a driver via a display device (human-machine interface (HMI) or the like) of the vehicle 3. As a result, the driver can, for example, decelerate or steer the vehicle 3 as necessary to increase the amount of electric power transmission. The vehicle 3 may automatically be controlled to increase the amount of electric power transmission based on the estimation result from the position estimator 25.

The embodiments described above may be implemented in an combination. For example, in the third to fifth embodiments, the filter circuit 8 may be provided between the magnetic field detector 7 and the controller 22 or between the magnetic field detector 7 and the ECU 34 similarly to the second embodiment.

The fifth embodiment may be combined with the third embodiment, and the vehicle 3 may include a plurality of magnetic field detectors 7 spaced away from each other along the vehicle width direction of the vehicle 3. Also in this case, the magnetic field detectors 7 are provided along the direction perpendicular to the traveling direction of the vehicle 3. The fifth embodiment may be combined with the fourth embodiment, and the vehicle 3 may include a plurality of magnetic field detectors 7 and a plurality of transmission-side resonance circuits 43 spaced away from each other along the vehicle width direction of the vehicle 3. Also in this case, the magnetic field detectors 7 and the transmission-side resonance circuits 43 are provided along the direction perpendicular to the traveling direction of the vehicle 3.

What is claimed is:

1. A contactless power supply system configured to perform contactless electric power transmission of magnetic field resonance coupling between a ground-side device and a mobile body, the contactless power supply system comprising:
a transmission-side resonance circuit configured to transmit electric power;
a reception-side resonance circuit configured to receive the electric power from the transmission-side resonance circuit;
an alternating current magnetic field generation circuit configured to generate alternating current magnetic field for detecting a relative positional relationship between the transmission-side resonance circuit and the reception-side resonance circuit; and
a magnetic field detector configured to detect the alternating current magnetic field, wherein a frequency of the alternating current magnetic field is different from a resonance frequency of each of the transmission-side resonance circuit and the reception-side resonance circuit.

2. The contactless power supply system according to claim 1, wherein the frequency of the alternating current magnetic field is lower than the resonance frequency.

3. The contactless power supply system according to claim 1, further comprising a filter circuit configured to filter an output of the magnetic field detector, wherein the filter circuit is configured to pass a signal having the frequency of the alternating current magnetic field and attenuate a signal having the resonance frequency.

4. The contactless power supply system according to claim 1, wherein:
the transmission-side resonance circuit and the magnetic field detector are provided in one of the mobile body and the ground-side device; and
the reception-side resonance circuit and the alternating current magnetic field generation circuit are provided in another one of the mobile body and the ground-side device.

5. The contactless power supply system according to claim 4, wherein:
the transmission-side resonance circuit and the magnetic field detector are provided in the ground-side device; and
the reception-side resonance circuit and the alternating current magnetic field generation circuit are provided in the mobile body.

6. The contactless power supply system according to claim 4, where:
the transmission-side resonance circuit and the magnetic field detector are provided in the mobile body; and
the reception-side resonance circuit and the alternating current magnetic field generation circuit are provided in the ground-side device.

7. The contactless power supply system according to claim 1, wherein a plurality of the magnetic field detectors is provided along a direction perpendicular to a traveling direction of the mobile body.

8. The contactless power supply system according to claim 7, further comprising:
a position estimator configured to estimate the relative positional relationship between the transmission-side resonance circuit and the reception-side resonance circuit based on an output of the magnetic field detector; and
a power supply controller configured to control the contactless electric power transmission based on the relative positional relationship estimated by the position estimator, wherein the power supply controller is configured to prohibit electric power transmission from the transmission-side resonance circuit to the reception-side resonance circuit when the transmission-side resonance circuit and the reception-side resonance circuit are misaligned in the direction perpendicular to the traveling direction of the mobile body.

9. The contactless power supply system according to claim 7, further comprising:
a position estimator configured to estimate the relative positional relationship between the transmission-side resonance circuit and the reception-side resonance circuit based on a output of the magnetic field detector; and
a power supply controller configured to control the contactless electric power transmission based on the relative positional relationship estimated by the position estimator, wherein:
a plurality of the transmission-side resonance circuits is provided along the direction perpendicular to the traveling direction of the mobile body; and
the power supply controller is configured to switch the transmission-side resonance circuit that transmits the electric power to the reception-side resonance circuit based on the relative positional relationship in the direction perpendicular to the traveling direction of the mobile body.

10. The contactless power supply system according to claim 1, wherein the alternating current magnetic field includes identification information of the mobile body.

11. A position estimation method to be applied to a contactless power supply system configured to perform contactless electric power transmission of magnetic field resonance coupling between a ground-side device and a mobile body, the contactless power supply system including an alternating current magnetic field generation circuit, a magnetic field detector, a transmission-side resonance circuit, and a reception-side resonance circuit, the position estimation method comprising:
generating an alternating current magnetic field by the alternating current magnetic field generation circuit;
detecting the alternating current magnetic field by the magnetic field detector; and
estimating, based on an output of the magnetic field detector, a relative positional relationship between the transmission-side resonance circuit that transmits electric power and the reception-side resonance circuit that receives the electric power from the transmission-side resonance circuit, wherein a frequency of the alternating current magnetic field is different from a resonance frequency of each of the transmission-side resonance circuit and the reception-side resonance circuit.

12. A mobile body configured such that electric power is contactlessly transmitted from a ground-side device, the mobile body comprising:
a reception-side resonance circuit configured to receive the electric power transmitted from a transmission-side resonance circuit provided in the ground-side device; and
an alternating current magnetic field generation circuit configured to generate an alternating current magnetic field for detecting a relative positional relationship between the transmission-side resonance circuit and the reception-side resonance circuit, wherein a frequency of the alternating current magnetic field is different from a resonance frequency of each of the transmission-side resonance circuit and the reception-side resonance circuit.

13. A power supply device configured to perform contactless power supply to a mobile body, the power supply device comprising:
a transmission-side resonance circuit configured to transmit electric power to a reception-side resonance circuit of the mobile body;
a magnetic field detector configured to detect a magnetic field around the power supply device; and
a control device configured to extract an alternating current magnetic field having a specific frequency from e output of the magnetic field detector and detect a relative positional relationship between the transmission-side resonance circuit and the reception-side resonance circuit based on the alternating current magnetic field having the specific frequency, wherein the specific frequency is different from a resonance frequency of each of the transmission-side resonance circuit and the reception-side resonance circuit.
